(19) United States
(12) Patent Application Publication
(10) Pub. No.: US 2025/0344452 A1
(43) Pub. Date: Nov. 6, 2025

(54) SEMICONDUCTOR DEVICE INCLUDING OXIDE SEMICONDUCTOR AND METHOD FOR FABRICATING THE SAME

(71) Applicant: SK hynix Inc., Gyeonggi-do (KR)

(72) Inventors: Jun Hwe CHA, Gyeonggi-do (KR); Wha Young KIM, Gyeonggi-do (KR)

(21) Appl. No.: 18/929,635

(22) Filed: Oct. 29, 2024

(30) Foreign Application Priority Data
May 2, 2024 (KR) 10-2024-0058432

(51) Int. Cl. H01L 29/786; H01L 29/32; H01L 29/66

(52) U.S. Cl. CPC H10D 30/6755; H10D 30/031; H10D 62/53

(57) ABSTRACT

A semiconductor device includes a crystalline first oxide semiconductor pattern having at least one etched surface; and a crystalline second oxide semiconductor layer disposed on the etched surface of the first oxide semiconductor pattern. A method for fabricating a semiconductor device includes forming a crystalline first oxide semiconductor layer over a substrate; forming a first oxide semiconductor pattern having an etched side surface by selectively etching the first oxide semiconductor layer; and forming a crystalline second oxide semiconductor layer on the side surface of the first oxide semiconductor pattern.

### CROSS-REFERENCE TO RELATED APPLICATIONS

The present application claims priority under 35 U.S.C 119(a) to Korean Patent Application No. 10-2024-0058432, filed on May 2, 2024, which is incorporated herein by reference in its entirety.

### BACKGROUND

### 1. Field

Various embodiments of the present invention relate generally to a semiconductor technology and, more particularly, to a semiconductor device including an oxide semiconductor, and a method for fabricating the same.

### 2. Description of the Related Art

Typically, amorphous silicon or polysilicon is mainly used for a semiconductor layer in a semiconductor device, such as a transistor. Amorphous silicon has advantages of being relatively inexpensive and capable of securing uniform device characteristics through a simple process, but has a disadvantage of low carrier mobility. Polysilicon may be obtained by crystallizing amorphous silicon and may have relatively high carrier mobility. However, a recrystallization process is required to form the polysilicon, and it is difficult to secure uniform device characteristics.

Recently, an oxide semiconductor is being proposed as a semiconductor material having the advantages of both polysilicon and amorphous silicon, that is, high carrier mobility, which is an advantage of polysilicon, and uniform device characteristics, which is an advantage of amorphous silicon.

### SUMMARY

Embodiments of the present invention are directed to a semiconductor device that may compensate for etching damage of an oxide semiconductor, and a method for fabricating the semiconductor device.

In accordance with an embodiment of the present invention, a semiconductor device is provided which includes a crystalline first oxide semiconductor pattern having at least one etched surface; and a crystalline second oxide semiconductor layer disposed on the etched surface of the first oxide semiconductor pattern.

In accordance with another embodiment of the present invention, a method for fabricating a semiconductor device is provided which includes forming a crystalline first oxide semiconductor layer over a substrate; forming a first oxide semiconductor pattern having an etched side surface by selectively etching the first oxide semiconductor layer; and forming a crystalline second oxide semiconductor layer on the side surface of the first oxide semiconductor pattern.

In accordance with an embodiment of the present invention, a method for fabricating a semiconductor device includes providing a crystalline first oxide semiconductor pattern over a substrate; forming an etched surface by exposing at least a portion of a top surface of the first oxide semiconductor pattern to an etching process; and forming a second oxide semiconductor layer on the etched surface.

### BRIEF DESCRIPTION OF THE DRAWINGS

FIGS. 1A to 1C are cross-sectional views illustrating a semiconductor device and a method for fabricating the same in accordance with an embodiment of the present invention.

FIGS. 2A to 2F are cross-sectional views illustrating a semiconductor device and a method for fabricating the same in accordance with another embodiment of the present invention.

FIGS. 3A to 3C are cross-sectional views illustrating a semiconductor device and a method for fabricating the same in accordance with another embodiment of the present invention.

FIG. 4 is a cross-sectional view illustrating a semiconductor device in accordance with another embodiment of the present invention.

FIGS. 5A and 5B are cross-sectional views illustrating a semiconductor device and a method for fabricating the same in accordance with another embodiment of the present invention.

FIGS. 6A to 6C are cross-sectional views illustrating a semiconductor device and a method for fabricating the same in accordance with another embodiment of the present invention.

### DETAILED DESCRIPTION

Hereinafter, the various embodiments of the present invention will be described in detail with reference to the attached drawings.

Various embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout this disclosure, like reference numerals refer to like parts throughout the various figures and embodiments of the present invention. The drawings are not necessarily to scale and in some instances, proportions may have been exaggerated in order to clearly illustrate features of the embodiments. When a first layer is referred to as being “on” a second layer or “on” a substrate, it not only refers to a case where the first layer is formed directly on the second layer or the substrate but also a case where a third layer exists between the first layer and the second layer or the substrate.

An oxide semiconductor may be used as a semiconductor element in a semiconductor device, such as a channel of a transistor. The oxide semiconductor may be exposed to an etching process for patterning itself or other constituent elements, and accordingly, at least a portion of the oxide semiconductor may have a surface exposed to the etching process (which is, hereinafter, referred to as an etched surface). Etching damage may occur on the etched surface of the oxide semiconductor. The term “etching damage” refers to a decrease in the thickness/width/volume of the oxide semiconductor caused by excessive etching and the like, and/or to surface irregularities formed on the etched surface. As the integration of the semiconductor device increases and, thus, the size of the patterned oxide semiconductor decreases, the etching damage may have diverse adverse effects on the characteristics of the semiconductor device. Furthermore, complications such as unintentional changes in the physical properties of the oxide semiconductor may occur. For example, impurities such as hydrogen ions and the like may penetrate into the oxide semiconductor through the etched surface, thereby increasing oxygen vacancies in the oxide semiconductor. Hereafter, a method for compensating for the etching damage of an oxide semiconductor and preventing/decreasing hydrogen ions from penetrating into the oxide semiconductor will be described.

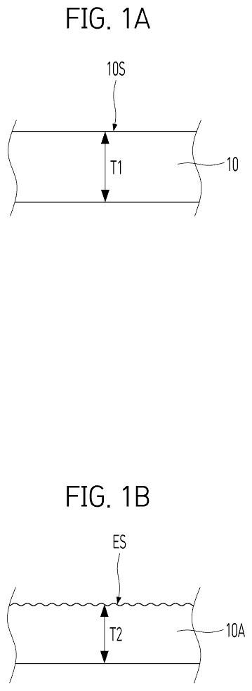

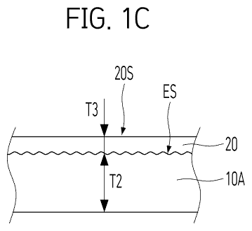

FIGS. 1A to 1C are cross-sectional views illustrating a semiconductor device and a method for fabricating the same in accordance with an embodiment of the present invention. FIG. 1C illustrates a semiconductor device in accordance with the embodiment of the present invention, and FIGS. 1A and 1B illustrate an intermediate process for fabricating the semiconductor device of FIG. 1C.

First, the method for fabricating a semiconductor device will be described.

Referring to FIG. 1A, a first oxide semiconductor layer 10 may be provided. The first oxide semiconductor layer 10 may include an oxide of at least one metal. The at least one metal may be selected from group 12, 13, or 14 metals. Examples of such metals include zinc (Zn), indium (In), gallium (Ga), tin (Sn), cadmium (Cd), germanium (Ge), hafnium (Hf) and the like. For example, the first oxide semiconductor layer 10 may include diverse oxide semiconductors, such as indium gallium zinc oxide (IGZO), indium zinc tin oxide (IZTO), zinc tin oxide (ZTO), indium gallium oxide (IGO) and the like. The first oxide semiconductor layer 10 may be formed through diverse deposition methods. The first oxide semiconductor layer 10 may be in a crystalline state.

The surface of the first oxide semiconductor layer 10 which is exposed to the subsequent etching process and which is described in FIG. 1B, may be referred to simply as a first surface 10S.

Referring to FIG. 1B, the first surface 10S of the first oxide semiconductor layer 10 may be exposed to an etching process, thereby forming a first oxide semiconductor pattern 10A having an etched surface ES. The first oxide semiconductor pattern 10A may refer to the first oxide semiconductor layer 10 exposed to the etching process, and the etched surface ES may refer to the first surface 10S exposed to the etching process. The etching process may include a dry etching process, a wet etching process, or a combination thereof. Diverse etching damages may occur on the etched surface ES of the first oxide semiconductor pattern 10A.

For example, the etched surface ES of the oxide semiconductor pattern 10A may be depressed more than the first surface 10S of the first oxide semiconductor layer 10 due to excessive etching of the first oxide semiconductor layer 10. Thus, the thickness T2 of the first oxide semiconductor pattern 10A may be decreased compared to the thickness T1 of the first oxide semiconductor layer 10. In some cases, there may be no or almost no excessive etching of the first oxide semiconductor layer 10, and in this case, the thickness T1 of the first oxide semiconductor layer 10 and the thickness T2 of the first oxide semiconductor pattern 10A may be substantially the same. In short, the thickness T2 of the first oxide semiconductor pattern 10A may be equal to or smaller than the thickness T1 of the first oxide semiconductor layer 10. According to this embodiment of the present invention, the first surface 10S may be illustrated in a horizontal direction, and accordingly, the decrease in the thickness T1 of the first oxide semiconductor layer 10 during the etching process is described, but the concepts of the present invention are not limited thereto. According to another embodiment of the present invention, the first surface 10S may correspond to the vertical direction, and in this case, the width of the first oxide semiconductor layer 10 in the horizontal direction may be decreased during the etching process.

Also, for another example, irregularities may be formed on the etched surface ES of the first oxide semiconductor pattern 10A. Accordingly, the flatness of the etched surface ES of the first oxide semiconductor pattern 10A may be lower than the flatness of the first surface 10S of the first oxide semiconductor layer 10. Also, the roughness of the etched surface ES of the first oxide semiconductor pattern 10A may be greater than the roughness of the first surface 10S of the first oxide semiconductor layer 10.

Referring to FIG. 1C, a second oxide semiconductor layer 20 may be formed on the etched surface ES of the first oxide semiconductor pattern 10A. The second oxide semiconductor layer 20 may be formed on the etched surface ES of the first oxide semiconductor pattern 10A by a vapor deposition method. The second oxide semiconductor layer 20 may be formed on the etched surface ES of the first oxide semiconductor pattern 10A by a liquid-phase deposition method. Other suitable methods may also be used. For example, the second oxide semiconductor layer 20 may be formed by using the first oxide semiconductor pattern 10A as a seed crystal, which is similar to an epitaxial growth method. The second oxide semiconductor layer 20 formed in this way may compensate for diverse etching damages occurring in the first oxide semiconductor pattern 10A while forming a predetermined semiconductor element, along with the first oxide semiconductor pattern 10A. For example, a predetermined semiconductor element may be a channel of a transistor.

The second oxide semiconductor layer 20 may compensate for the decrease in the thickness T1 of the first oxide semiconductor layer 10. Accordingly, the sum of the thickness T3 of the second oxide semiconductor layer 20 and the thickness T2 of the first oxide semiconductor pattern 10A may have a value which is equal to or greater than the thickness T1 of the first oxide semiconductor layer 10. In the case where the second oxide semiconductor layer 20 forms a semiconductor element together with the first oxide semiconductor pattern 10A, the first oxide semiconductor pattern 10A may be the main element and the second oxide semiconductor layer 20 may be a supplementary element. Accordingly, the thickness T3 of the second oxide semiconductor layer 20 may be smaller than the thickness T2 of the first oxide semiconductor pattern 10A.

The second oxide semiconductor layer 20 may prevent various defects caused by the irregularities of the etched surface ES of the first oxide semiconductor pattern 10A by covering the irregularities. The second oxide semiconductor layer 20 may have a surface contacting the etched surface ES and a surface opposite to the first surface, i.e., opposite to the etched surface ES. Hereinafter, the surface of the second oxide semiconductor layer 20 that is opposite to the etched surface ES may be referred to as a first surface 20S of the second oxide semiconductor layer 20. The flatness of the first surface 20S of the second oxide semiconductor layer 20 may be greater than the flatness of the etched surface ES of the first oxide semiconductor pattern 10A. Also, the roughness of the first surface 20S of the second oxide semiconductor layer 20 may be smaller than the roughness of the etched surface ES of the first oxide semiconductor pattern 10A.

The semiconductor device illustrated in FIG. 1C may be fabricated by the fabrication described above.

Referring back to FIG. 1C, the semiconductor device may include a crystalline first oxide semiconductor pattern 10A, and a crystalline second oxide semiconductor layer 20 disposed on the etched surface ES of the first oxide semiconductor pattern 10A.

The etched surface ES of the first oxide semiconductor pattern 10A may include irregularities. Accordingly, the roughness of the etched surface ES of the first oxide semiconductor pattern 10A may be greater than the roughness of the first surface 20S of the second oxide semiconductor layer 20. Also, the flatness of the etched surface ES of the first oxide semiconductor pattern 10A may be smaller than the flatness of the first surface 20S of the second oxide semiconductor layer 20. The thickness T3 or width of the second oxide semiconductor layer 20 may be smaller than the thickness T2 or width of the first oxide semiconductor pattern 10A.

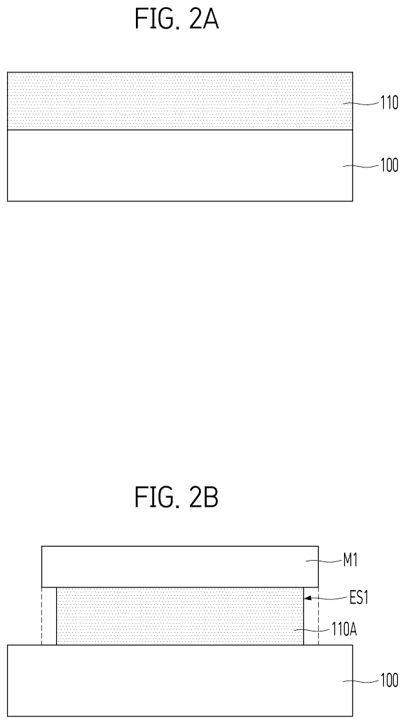

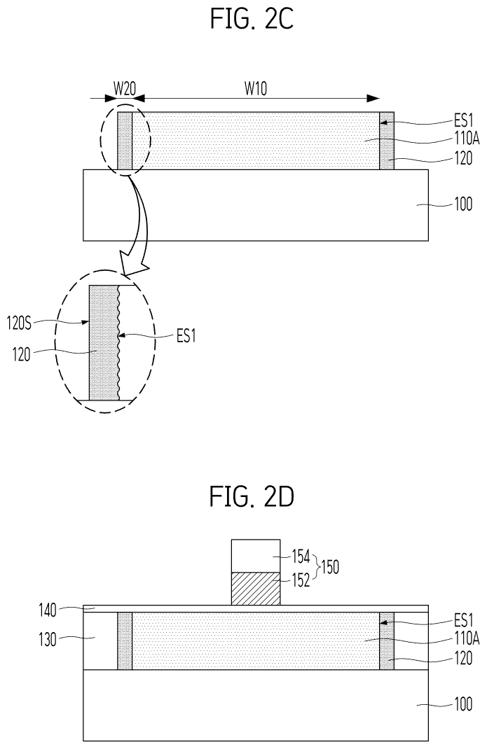

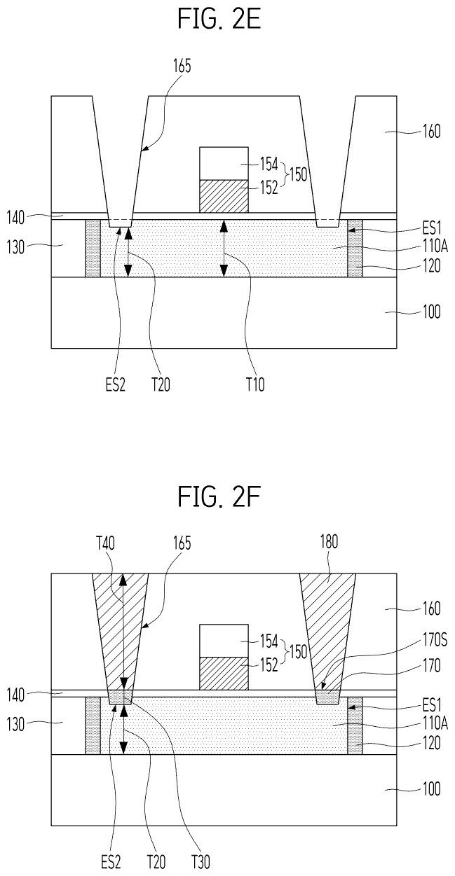

The first oxide semiconductor pattern 10A and the second oxide semiconductor layer 20 may be formed of the same material. For example, the constituent elements of the first oxide semiconductor pattern 10A and their concentrations and the constituent elements of the second oxide semiconductor layer 20 and their concentrations may be substantially the same. For example, the first oxide semiconductor pattern 10A and the second oxide semiconductor layer 20 may include IGZO, and the concentrations of indium, gallium, zinc, and oxygen in the first oxide semiconductor pattern 10A may be substantially the same to the concentrations of indium, gallium, zinc, and oxygen in the second oxide semiconductor layer 20. However, the concepts of the present invention are not limited thereto. For example, in an embodiment, the characteristics of the semiconductor element formed by the first oxide semiconductor pattern 10A and the second oxide semiconductor layer 20 may be improved by forming the second oxide semiconductor layer 20 of a material that is different from the material of the first oxide semiconductor pattern 10A. For example, in an embodiment, the constituent elements of the second oxide semiconductor layer 20 and the constituent elements of the first oxide semiconductor pattern 10A may be the same but the concentrations of the constituent elements may be different. In another embodiment, at least one of the constituent elements of the second oxide semiconductor layer 20 may be different from the constituent elements of the first oxide semiconductor pattern 10A. Diverse examples of the constituent elements may be described with reference to FIGS. 2A to 6C below.

The present inventive method for compensating for the etching damage of the oxide semiconductor may be applied to diverse semiconductor devices, particularly semiconductor devices including transistors, and methods for fabricating the same. Hereinafter, various other embodiments are described with reference to FIGS. 2A to 6C. These embodiments are described by focusing on any differences from the above-described embodiment of the present invention.

FIGS. 2A to 2F are cross-sectional views illustrating a semiconductor device and a method for fabricating the same in accordance with another embodiment of the present invention.

First, the method for fabricating a semiconductor device may be described.

Referring to FIG. 2A, a first oxide semiconductor layer 110 may be formed over a substrate 100. The first oxide semiconductor layer 110 may be formed directly on a top surface of the substrate 100. The first oxide semiconductor layer 110 may be in direct contact with the top surface of the substrate 100.

The substrate 100 may include one or more layers. The one or more layers of the substrate may be made of one or more materials. The substrate 100 may include diverse materials such as semiconductor materials and dielectric materials. Although not illustrated, an uppermost portion of the substrate 100 may include a dielectric material.

The first oxide semiconductor layer 110 may cover the top surface of the substrate 100. The first oxide semiconductor layer 110 may be formed by any suitable deposition method. The first oxide semiconductor layer 110 may be in a crystalline state.

Referring to FIG. 2B, a first oxide semiconductor pattern 110A may be formed by forming a mask pattern M1 over the first oxide semiconductor layer 110 and etching the first oxide semiconductor layer 110 by using the mask pattern M1 as an etch barrier.

The first oxide semiconductor pattern 110A may have an island shape having a width in the horizontal direction that is greater than a width in the vertical direction. The horizontal direction refers to a direction substantially parallel to the top surface of the substrate 100. The vertical direction refers to a direction substantially perpendicular to the top surface of the substrate 100.

The side surface of the first oxide semiconductor pattern 110A may correspond to the surface exposed to the etching process, that is, the etched surface. The side surface of the first oxide semiconductor pattern 110A may be referred to as a first etched surface ES1. The first etched surface ES1 may have a shape that is depressed inwardly compared with the side surface of the mask pattern M1 due to the etching damage. However, the concepts of the present invention are not limited to this, and the first etched surface ES1 may be substantially aligned with the side surface of the mask pattern M1 (see the dotted line). Also, irregularities may be formed on the first etched surface ES1 due to the etching damage as described below with reference to FIG. 2C.

Referring now to FIG. 2C, a second oxide semiconductor layer 120 may be formed on the first etched surface ES1. The second oxide semiconductor layer 120 may be formed by a suitable deposition method including, for example, a vapor deposition method or a liquid-phase deposition method. In an embodiment, the second oxide semiconductor layer 120 may be formed by using the first oxide semiconductor pattern 110A as a seed crystal, i.e., similar to an epitaxial growth method. The second oxide semiconductor layer 120 may be formed in a state that the mask pattern M1 is already formed. After the second oxide semiconductor layer 120 is formed, the mask pattern M1 may be removed.

The second oxide semiconductor layer 120 may have a shape surrounding the first etched surface ES1 on the side surface of the island-shaped first oxide semiconductor pattern 110A, that is, the first etched surface ES1. Accordingly, the second oxide semiconductor layer 120 may compensate for the etching damage occurring on the side surface of the first oxide semiconductor pattern 110A. The second oxide semiconductor layer 120 may have a contact surface contacting the first etched surface ES1 of the first oxide semiconductor pattern 110A, and a first surface 120S opposite to the contact surface. The flatness of the first surface 120S of the second oxide semiconductor layer 120 may be greater than the flatness of the first etched surface ES1 of the first oxide semiconductor pattern 110A. Also, the roughness of the first surface 120S of the second oxide semiconductor layer 120 may be smaller than the roughness of the first etched surface ES1 of the first oxide semiconductor pattern 110A. The width W20 of the horizontal direction of the second oxide semiconductor layer 120 may be smaller than the width W10 of the horizontal direction of the first oxide semiconductor pattern 110A.

The second oxide semiconductor layer 120 may decrease and/or prevent any impurities such as hydrogen from penetrating into the first etched surface ES1 of the first oxide semiconductor pattern 110A. Since the constituent element of the first oxide semiconductor pattern 110A is partially lost so as to form a defect on the first etched surface ES1 of the first oxide semiconductor pattern 110A, diverse impurities used in the subsequent process, such as hydrogen and the like, may easily penetrate into the first oxide semiconductor pattern 110A. The second oxide semiconductor layer 120 may function to block the penetration of the impurities. Furthermore, when the second oxide semiconductor layer 120 functions as a reservoir for impurities and contains a specific element, the effect of blocking the penetration of the impurity may be increased further. For example, as the gallium concentration of the second oxide semiconductor layer 120 is increased, the hydrogen storage capacity of the second oxide semiconductor layer 120 may be increased. Therefore, the penetration of hydrogen into the first etched surface ES1 of the first oxide semiconductor pattern 110A may be decreased. In an embodiment, the first oxide semiconductor pattern 110A does not contain gallium, and the second oxide semiconductor layer 120 contains gallium. In another embodiment, the first oxide semiconductor pattern 110A contains gallium, and the second oxide semiconductor layer 120 contains gallium in a concentration greater than the gallium concentration of the first oxide semiconductor pattern 110A.

The first oxide semiconductor pattern 110A and the second oxide semiconductor layer 120 may provide a channel region and source/drain regions of a transistor, respectively. Although not illustrated, a plurality of structures may be arranged to be spaced apart from each other in the horizontal direction, each structure comprising the first oxide semiconductor pattern 110A and the second oxide semiconductor layer 120. The plurality of the structures may be formed at the same time.

Referring to FIG. 2D, an isolation layer 130 may be formed over the substrate 100 to fill the space excluding the first oxide semiconductor pattern 110A and the second oxide semiconductor layer 120. The isolation layer 130 may fill the space between the spaced apart structures of the first oxide semiconductor patterns 110A and the second oxide semiconductor layer 120. The isolation layer 130 may include any suitable dielectric material. The isolation layer 130 may include diverse dielectric materials, such as silicon oxide, silicon nitride, silicon oxynitride, or a combination thereof. The isolation layer 130 may be formed by depositing a dielectric material that covers the process result of FIG. 2C, and then performing a planarization process until the top surfaces of the first oxide semiconductor pattern 110A and the second oxide semiconductor layer 120 are exposed. Any suitable deposition method may be used.

Subsequently, a gate dielectric layer 140 may be formed over the first oxide semiconductor pattern 110A, the second oxide semiconductor layer 120, and the isolation layer 130. The gate dielectric layer 140 may be formed by diverse deposition methods. The gate dielectric layer 140 may include diverse dielectric materials, such as silicon oxide, silicon nitride, silicon oxynitride and the like, or a high-k material whose dielectric constant is higher than the dielectric constant of silicon oxide.

Subsequently, a gate structure 150 may be formed over the gate dielectric layer 140. The gate structure 150 may include a gate electrode layer 152 formed over the gate dielectric layer 140 and a gate passivation layer 154 formed over the gate electrode layer 152. The gate passivation layer 154 may be formed on the gate electrode layer 152. The gate structure 150 may be formed by depositing a conductive material for forming the gate electrode layer 152 and a dielectric material for forming the gate passivation layer 154 over the gate dielectric layer 140 and then selectively etching them. The gate passivation layer 154 may function as a hard mask, when the conductive material for forming the gate electrode layer 152 is etched. The gate electrode layer 152 may include diverse conductive materials, for example, a metal such as platinum (Pt), tungsten (W), aluminum (Al), copper (Cu), tantalum (Ta), titanium (Ti), ruthenium (Ru), molybdenum (Mo) and the like, a metal compound thereof, or a metal alloy thereof, and the gate electrode layer 152 may have a single-layer structure or a multi-layer structure. The gate passivation layer 154 may include diverse dielectric materials such as silicon oxide, silicon nitride, silicon oxynitride and the like, and the gate passivation layer 154 may have a single-layer structure or a multi-layer structure.

A portion of the first oxide semiconductor pattern 110A overlapping with the gate structure 150 may form a channel region of the transistor. The portions of the first oxide semiconductor pattern 110A disposed on both sides of the gate structure 150 may form the source/drain regions of the transistor. For example, a portion of the first oxide semiconductor pattern 110A disposed on one side of the gate structure 150 may form the source region of the transistor, and a portion of the first oxide semiconductor pattern 110A disposed on the other side of the gate structure 150 may form the drain region of the transistor.

Referring to FIG. 2E, an inter-layer dielectric layer 160 that covers the process result of FIG. 2D may be formed. The inter-layer dielectric layer 160 may be formed by a deposition process. The inter-layer dielectric layer 160 may include diverse dielectric materials, such as silicon oxide, silicon nitride, silicon oxynitride and the like. The top surface of the inter-layer dielectric layer 160 may be formed to be disposed at a height which is equal to or higher than the top surface of the gate structure 150.

Subsequently, a contact hole 165 exposing a portion of the first oxide semiconductor pattern 110A may be formed by selectively etching the inter-layer dielectric layer 160 and the gate dielectric layer 140. Here, the contact hole 165 may be formed to respectively expose the source region and the drain region of the transistor of the first oxide semiconductor pattern 110A. The contact hole 165 may have a tapered shape with a decreasing width in a direction approaching the first oxide semiconductor pattern 110A.

Here, a portion of the top surface of the first oxide semiconductor pattern 110A corresponding to the bottom surface of the contact hole 165 is the surface exposed to the etching process, and is, hereinafter, referred to as a second etched surface ES2. Also, the remaining portion of the top surface of the first oxide semiconductor pattern 110A, excluding the second etched surface ES2, may be, hereinafter, referred to as a remaining top surface portion. The second etched surface ES2 may have a shape that is depressed lower than the remaining top surface portion of the first oxide semiconductor pattern 110A due to the etching damage. The height from the top surface of the substrate 100 to the second etched surface ES2, that is, the thickness T20 of the portion of the first oxide semiconductor pattern 110A corresponding to the second etched surface ES2, may be smaller than the height from the top surface of the substrate 100 to the remaining top surface portion of the first oxide semiconductor pattern 110A, that is, the thickness T10 of the remaining portion of the first oxide semiconductor pattern 110A that does not correspond to the second etched surface ES2. However, the concepts of the present invention are not limited to this, and the second etched surface ES2 may be disposed at substantially the same height as the remaining top surface portion of the first oxide semiconductor pattern 110A (see the dotted line). Also, irregularities may be formed on the second etched surface ES2 due to the etching damage.

Referring to FIG. 2F, a third oxide semiconductor layer 170 may be formed on the second etched surface ES2. The third oxide semiconductor layer 170 may be formed by a suitable deposition method. For example, in an embodiment the third oxide semiconductor layer 170 may be formed by a vapor deposition method. In another embodiment, the third oxide semiconductor layer 170 may be formed by a liquid-phase deposition method. The third oxide semiconductor layer 170 may be formed by using the first oxide semiconductor pattern 110A as a seed crystal, i.e., similar to an epitaxial growth method.

The third oxide semiconductor layer 170 may be formed to cover the second etched surface ES2 by filling a lower portion of the contact hole 165. Accordingly, the third oxide semiconductor layer 170 may compensate for the etching damage occurring on the second etched surface ES2 of the first oxide semiconductor pattern 110A. The third oxide semiconductor layer 170 may have a bottom surface contacting the second etched surface ES2 of the first oxide semiconductor pattern 110A, and a top surface opposite to the bottom surface, that is, a first surface 170S. The flatness of the first surface 170S of the third oxide semiconductor layer 170 may be greater than the flatness of the second etched surface ES2 of the first oxide semiconductor pattern 110A. Also, the roughness of the first surface 170S of the third oxide semiconductor layer 170 may be smaller than the roughness of the second etched surface ES2 of the first oxide semiconductor pattern 110A. The thickness T30 of the third oxide semiconductor layer 170 may be smaller than the thickness T20 of the portion of the first oxide semiconductor pattern 110A corresponding to the second etched surface ES2.

The third oxide semiconductor layer 170 may decrease and/or

prevent any impurities such as hydrogen from penetrating into the second etched surface ES2 of the first oxide semiconductor pattern 110A. Furthermore, when the third oxide semiconductor layer 170 functions as a reservoir for impurities and contains a specific element, the effect of blocking the penetration of the impurity may be increased further. For example, as the gallium concentration of the third oxide semiconductor layer 170 is increased, the hydrogen storage capacity of the third oxide semiconductor layer 170 may be increased, thereby decreasing the penetration of hydrogen through the second etched surface ES2 of the first oxide semiconductor pattern 110A. Even though the first oxide semiconductor pattern 110A does not contain gallium, the third oxide semiconductor layer 170 may contain gallium. Also, when the first oxide semiconductor pattern 110A contains gallium, the third oxide semiconductor layer 170 may contain gallium in a concentration greater than the gallium concentration of the first oxide semiconductor pattern 110A.

Also, the third oxide semiconductor layer 170 may further include an element that may lower the resistance of the third oxide semiconductor layer 170 to decrease the contact resistance between the contact plug 180 (see FIG. 2F), and the first oxide semiconductor pattern 110A. An example of such element is indium. It has been found that as the indium concentration of the third oxide semiconductor layer 170 is increased, the resistance of the third oxide semiconductor layer 170 is decreased. Even though the first oxide semiconductor pattern 110A does not contain indium, the third oxide semiconductor layer 170 may contain indium. Also, when the first oxide semiconductor pattern 110A contains indium, the third oxide semiconductor layer 170 may contain indium in a concentration greater than the indium concentration of the first oxide semiconductor pattern 110A. For example, when the first oxide semiconductor pattern 110A includes a typical IGZO, that is, IGZO satisfying the stoichiometric ratio, the third oxide semiconductor pattern 170 may include indium-rich IGZO. Indium-rich IGZO may refer to a material having a higher indium content than the contents of gallium and zinc, for example, a material having an indium content of approximately 40% or more. Since the indium-rich IGZO has a lower resistance than the typical IGZO, it may have metallic characteristics. As a result, the resistance of the third oxide semiconductor layer 170 may be smaller than the resistance of the first oxide semiconductor pattern 110A.

Referring now to FIG. 2F, a contact plug 180 may be formed to fill the remaining space of the contact hole 165 where the third oxide semiconductor layer 170 is formed. The contact plug 180 may be formed following the formation of the third oxide semiconductor layer 170. The contact plug 180 may be formed by depositing a conductive material to have a thickness that sufficiently fills the contact hole 165 and then performing a planarization process to expose the top surface of the inter-layer dielectric layer 160. The contact plug 180 may include diverse conductive materials, for example, a metal such as platinum (Pt), tungsten (W), aluminum (Al), copper (Cu), tantalum (Ta), titanium (Ti), ruthenium (Ru), molybdenum (Mo) and the like, a metal compound thereof, or a metal alloy thereof. For ensuring smooth current flow from the first oxide semiconductor pattern 110A through the third oxide semiconductor layer 170 and the contact plug 180, the resistance of the contact plug 180 may be smaller than the resistance of the third oxide semiconductor layer 170, and the thickness T40 of the contact plug 180 may be greater than the thickness T30 of the third oxide semiconductor layer 170. Since the contact plug 180 is disposed over the third oxide semiconductor layer 170 and fills the contact hole 165 together with the third oxide semiconductor layer 170, the side surface of the contact plug 180 and the side surface of the third oxide semiconductor layer 170 may be aligned with each other. The contact plug 180 may correspond to a source/drain electrode electrically connected to the source/drain region of the transistor.

The semiconductor device illustrated in FIG. 2F may be fabricated by the method for fabricating a semiconductor device described above.

Referring back to FIG. 2F, the semiconductor device in accordance with this embodiment of the present invention may include the first oxide semiconductor pattern 110A, a gate structure 150 formed over the first oxide semiconductor pattern 110A with the gate dielectric layer 140 interposed therebetween, and a contact plug 180 disposed on at least one side of the gate structure 150 and electrically connected to the first oxide semiconductor pattern 110A.

Here, the first oxide semiconductor pattern 110A may include the first etched surface ES1 formed on a side surface of the first oxide semiconductor pattern 110A, and the second etched surface ES2 formed on at least a portion of the top surface of the first oxide semiconductor pattern 110A. The second oxide semiconductor layer 120 may be formed on the first etched surface ES1 of the first oxide semiconductor pattern 110A, and the third oxide semiconductor layer 170 may be formed on the second etched surface ES2 of the first oxide semiconductor pattern 110A. The third oxide semiconductor layer 170 may be interposed between the contact plug 180 and the second etched surface ES2 of the first oxide semiconductor pattern 110A.

Since the constituent elements of the semiconductor device in accordance with this embodiment of the present invention have already been described in detail while describing the process of fabricating a semiconductor device, further detailed description on the constituent elements may be omitted herein.

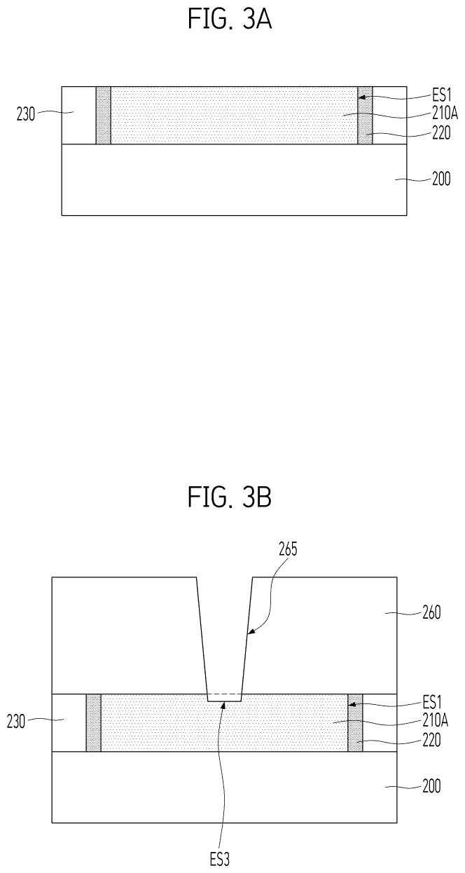

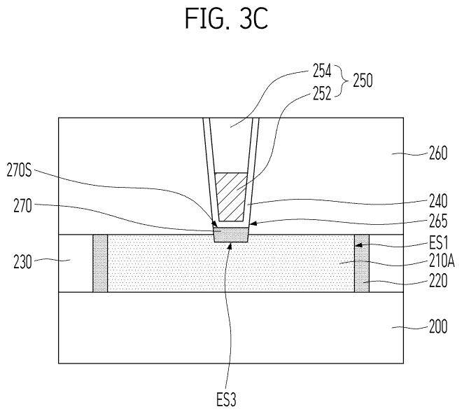

FIGS. 3A to 3C are cross-sectional views illustrating a semiconductor device and a method for fabricating the same in accordance with another embodiment of the present invention.

Referring to FIG. 3A, there is provided a structure including a substrate 200, a first oxide semiconductor pattern 210A formed over the substrate 200, a second oxide semiconductor layer 220 formed on a first etched surface ES1 of the first oxide semiconductor pattern 210A, and an isolation layer 230 filling the space excluding the first oxide semiconductor pattern 210A and the second oxide semiconductor layer 220 over the substrate 200. This structure may be formed by performing substantially the same processes as the processes of FIGS. 2A to 2C and a portion of the process of FIG. 2D described above.

Referring to FIG. 3B, an inter-layer dielectric layer 260 may be formed to cover the process result of FIG. 3A.

Subsequently, the inter-layer dielectric layer 260 may be selectively etched to form an opening 265 that exposes a portion of the first oxide semiconductor pattern 210A. Here, the opening 265 may provide a space in which a gate dielectric layer and a gate structure, which may be described later, are to be formed. Although not illustrated, from the perspective of a plan view, the opening 265 may have a shape of a line extending in a direction penetrating the cross-section.

For example, a portion of the top surface of the first oxide semiconductor pattern 210A corresponding to the bottom surface of the opening 265 may be a surface exposed to the etching process, and this may be, hereinafter, referred to as a third etched surface ES3. Also, the remaining portion of the top surface of the first oxide semiconductor pattern 210A, excluding the third etched surface ES3, may be, hereinafter, referred to as a remaining top surface portion of the first oxide semiconductor pattern 210A. The third etched surface ES3 may have a shape that is depressed lower than the remaining top surface portion of the first oxide semiconductor pattern 210A due to the etching damage. However, the concepts of the present invention are not limited to this, and the third etched surface ES3 may be disposed at substantially the same height as the remaining top surface portion of the first oxide semiconductor pattern 210A (see the dotted line). Also, irregularities may be formed on the third etched surface ES3 due to the etching damage.

Referring to FIG. 3C, a fourth oxide semiconductor layer 270 may be formed on the third etched surface ES3. For example, the fourth oxide semiconductor layer 270 may be formed by a vapor deposition method or a liquid-phase deposition method. The fourth oxide semiconductor layer 270 may be formed by using the first oxide semiconductor pattern 210A as a seed crystal, i.e., similar to an epitaxial growth method.

The fourth oxide semiconductor layer 270 may be formed to cover the third etched surface ES3 by filling the lower portion of the opening 265. Accordingly, the fourth oxide semiconductor layer 270 may compensate for the etching damage occurring on the third etched surface ES3 of the first oxide semiconductor pattern 210A. The fourth oxide semiconductor layer 270 may have a top surface opposite to the third etched surface ES3 of the first oxide semiconductor pattern 210A, that is, a first surface 270S. The flatness of the first surface 270S of the fourth oxide semiconductor layer 270 may be greater than the flatness of the third etched surface ES3 of the first oxide semiconductor pattern 210A. Also, the roughness of the first surface 270S of the fourth oxide semiconductor layer 270 may be smaller than the roughness of the third etched surface ES3 of the first oxide semiconductor pattern 210A. The thickness of the fourth oxide semiconductor layer 270 may be smaller than the thickness of a portion of the first oxide semiconductor pattern 210A corresponding to the third etched surface ES3.

The fourth oxide semiconductor layer 270 may decrease and/or prevent any impurities such as hydrogen from penetrating into the third etched surface ES3 of the first oxide semiconductor pattern 210A. Furthermore, when the fourth oxide semiconductor layer 270 functions as a reservoir for impurities and contains a specific element, the effect of blocking the penetration of the impurity may be increased further. For example, as the gallium concentration of the fourth oxide semiconductor layer 270 is increased, the hydrogen storage capacity of the fourth oxide semiconductor layer 270 may be increased, thereby decreasing the penetration of hydrogen through the third etched surface ES3 of the first oxide semiconductor pattern 210A. Even though the first oxide semiconductor pattern 210A does not contain gallium, the fourth oxide semiconductor layer 270 may contain gallium. Also, when the first oxide semiconductor pattern 210A contains gallium, the fourth oxide semiconductor layer 270 may contain gallium in a concentration greater than the gallium concentration of the first oxide semiconductor pattern 210A.

Subsequently, a gate dielectric layer 240 may be formed conformally along the sidewall and the bottom surface of the opening 265 in the remaining space of the opening 265 in which the fourth oxide semiconductor layer 270 is formed. The gate dielectric layer 240 may be formed to have a thickness that does not completely fill the opening 265.

Subsequently, a gate structure 250 may be formed to fill the remaining space of the opening 265 in which the gate dielectric layer 240 is formed. The gate structure 250 may include a gate electrode layer 252 that fills the lower portion of the remaining space of the opening 265 in which the gate dielectric layer 240 is formed, and a gate passivation layer 254 that fills the upper portion of the remaining space of the opening 265 in which the gate dielectric layer 240 is formed. The gate electrode layer 252 may be formed by depositing a conductive material having a thickness that sufficiently fills the remaining space of the opening 265 in which the gate dielectric layer 240 is formed, and then recessing the conductive material until the conductive material reaches a desired height. The gate passivation layer 254 may be formed by depositing a dielectric material that is thick enough to fill the remaining space of the opening 265 in which the gate electrode layer 252 is formed, and then performing a planarization process to expose the top surface of the inter-layer dielectric layer 260.

The semiconductor device illustrated in FIG. 3C may be fabricated by the method for fabricating a semiconductor device described above.

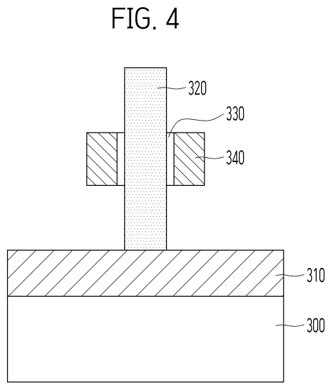

In the above-described embodiments of the present invention illustrated in FIGS. 2A to 3C, a planar-type transistor in which a channel is formed in a direction substantially parallel to the surface of the substrate has been described, but the concepts of the present invention are not limited thereto. The present invention may be applied to a vertical-type transistor in which the channel is formed in a direction substantially perpendicular to the surface of the substrate. This embodiment is described with reference to FIGS. 4 to 6C below.

FIG. 4 is a cross-sectional view illustrating a semiconductor device in accordance with another embodiment of the present invention.

Referring to FIG. 4, the semiconductor device may include a substrate 300, a first conductive line 310 disposed over the substrate 300 and extending in the horizontal direction, an oxide semiconductor pattern 320 disposed over the first conductive line 310 and having a pillar shape, and a gate electrode layer 340 disposed on a side surface of the oxide semiconductor pattern 320 with a gate dielectric layer 330 interposed therebetween.

According to this embodiment of the present invention, the oxide semiconductor pattern 320 may have a pillar shape so that the channel region of the transistor may be formed in a direction perpendicular to the top surface of the substrate 300. Here, the pillar shape may mean a shape whose width in the horizontal direction is smaller than the width in the vertical direction, that is, the thickness.

The portion of the oxide semiconductor pattern 320 that faces the gate electrode layer 340 may correspond to the channel region of the transistor while the portions of the oxide semiconductor pattern 320 disposed over and below the channel region may correspond to the source/drain regions of the transistor.

The first conductive line 310 may be coupled to the bottom surface of the oxide semiconductor pattern 320 to be electrically connected to the oxide semiconductor pattern 320, thereby supplying the required voltage or current to the oxide semiconductor pattern 320. The first conductive line 310 may correspond to a bit line.

The gate electrode layer 340 may face a portion of the side surface of the oxide semiconductor pattern 320 and may control the current flow in the channel region according to the voltage or current supplied to the gate electrode layer 340. According to this embodiment of the present invention, the gate electrode layer 340 is illustrated as being disposed on both sides of the oxide semiconductor pattern 320, but the concepts of the present invention are not limited thereto. The gate electrode layer 340 may have a shape surrounding the side surface of the oxide semiconductor pattern 320 or may face a portion of the side surface. Although not illustrated, the gate electrode layer 340 may have a line shape extending in a direction penetrating the cross section, and this gate electrode layer 340 may correspond to a word line.

The top surface of the oxide semiconductor pattern 320 may be electrically connected to another constituent element, such as a memory element.

Even when the vertical-type transistor is formed as described above, the oxide semiconductor pattern 320 may be exposed to an etching process, causing etching damage. A method for compensating for this etching damage will be described below.

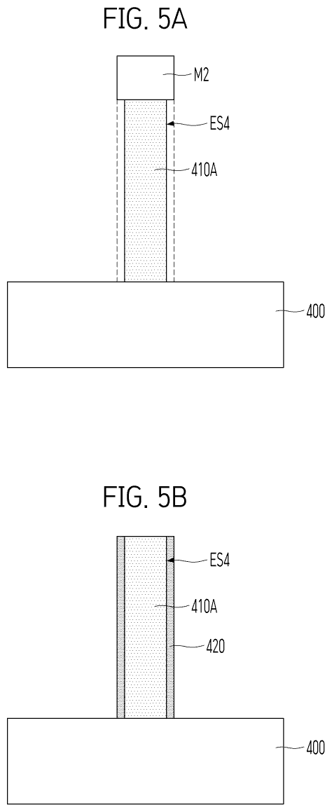

FIGS. 5A and 5B are cross-sectional views illustrating a semiconductor device and a method for fabricating the same in accordance with another embodiment of the present invention. In particular, these figures describe the process for forming the oxide semiconductor pattern 320 shown in FIG. 4.

Referring to FIG. 5A, a first oxide semiconductor pattern 410A may be formed by forming an oxide semiconductor layer over a substrate 400 and etching the oxide semiconductor layer by using the mask pattern M2.

The first oxide semiconductor pattern 410A may have a pillar shape whose width in the vertical direction, that is, the thickness, is greater than the width in the horizontal direction. The side surface of the first oxide semiconductor pattern 410A may be referred to as an etched surface ES4. The etched surface ES4 may have a shape that is depressed inwardly compared with the side surface of the mask pattern M2 due to the etching damage. However, the embodiments of the present invention are not limited to this, and the etched surface ES4 may be substantially aligned with the side surface of the mask pattern M2 (see the dotted line). Also, irregularities may be formed on the etched surface ES4 due to the etching damage.

Referring to FIG. 5B, a second oxide semiconductor layer 420 may be formed on the etched surface ES4. For example, the second oxide semiconductor layer 420 may be formed by a vapor deposition method or a liquid-phase deposition method. The second oxide semiconductor layer 420 may be formed by using the first oxide semiconductor pattern 410A as a seed crystal, which is similar to an epitaxial growth method. The second oxide semiconductor layer 420 may be formed in a state that the mask pattern M2 is already formed. After the second oxide semiconductor layer 420 is formed, the mask pattern M2 may be removed.

The second oxide semiconductor layer 420 may have a shape surrounding the side surface of the pillar-shaped first oxide semiconductor pattern 410A, that is, the etched surface ES4. Accordingly, the second oxide semiconductor layer 420 may compensate for the etching damage occurring on the side surface of the first oxide semiconductor pattern 410A.

The second oxide semiconductor layer 420 may decrease and/or prevent any impurities such as hydrogen from penetrating into the etched surface ES4 of the first oxide semiconductor pattern 410A. Furthermore, when the second oxide semiconductor layer 420 functions as a reservoir for impurities and contains a specific element, the effect of blocking the penetration of the impurity may be increased further. For example, the second oxide semiconductor layer 420 may include a gallium-rich oxide semiconductor with excellent hydrogen storage ability.

The first oxide semiconductor pattern 410A and the second oxide semiconductor layer 420 may correspond to the oxide semiconductor pattern 320 of FIG. 4 described above.

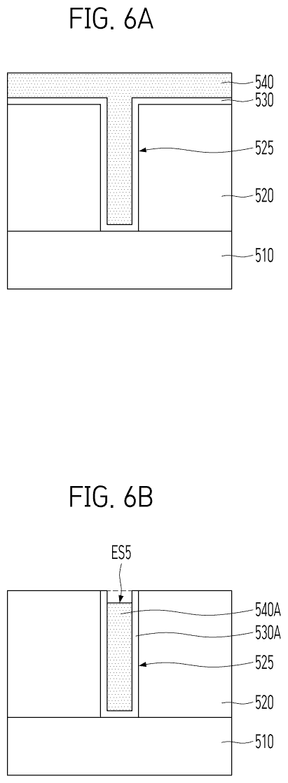

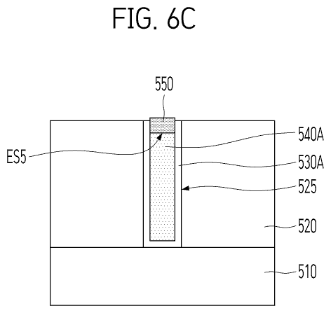

FIGS. 6A to 6C are cross-sectional views illustrating a semiconductor device and a method for fabricating the same in accordance with another embodiment of the present invention. In particular, these figures describe the process for forming the oxide semiconductor pattern 320 illustrated in FIG. 4.

Referring to FIG. 6A, a hole 525 providing a space for a pillar-shaped oxide semiconductor pattern to be formed may be formed by forming an inter-layer dielectric layer 520 over a substrate 500, and selectively etching the inter-layer dielectric layer 520.

Subsequently, a gate dielectric layer 530 may be conformally formed over the inter-layer dielectric layer 520 including the hole 525 to have a thin thickness that does not completely fill the hole 525. Then, a first oxide semiconductor layer 540 may be formed over the gate dielectric layer 530 to have a thickness that sufficiently fills the hole 525.

Referring to FIG. 6B, a first oxide semiconductor pattern 540A filling the hole 525 may be formed by performing an etching process, such as an etch-back process, onto the first oxide semiconductor layer 540. In this process, a portion of the gate dielectric layer 530 disposed on the top surface of the inter-layer dielectric layer 520 may be removed to form a gate dielectric pattern 530A filling the hole 525. The first oxide semiconductor pattern 540A may have a pillar shape, and the gate dielectric pattern 530A may have a shape surrounding the side surface of the first oxide semiconductor pattern 540A.

Here, the top surface of the first oxide semiconductor pattern 540A may correspond to an etched surface ES5. The etched surface ES5 may have a shape that is depressed lower than the top surface of the inter-layer dielectric layer 520 due to the etching damage. However, the embodiments of the present invention are not limited to this, and the etched surface ES5 may be disposed at substantially the same height as the top surface of the inter-layer dielectric layer 520 (see the dotted line). Also, irregularities may be formed on the etched surface ES5 due to the etching damage.

Referring to FIG. 6C, a second oxide semiconductor layer 550 may be formed on the etched surface ES5. The second oxide semiconductor layer 550 may be formed by any suitable deposition method, including, for example, a vapor deposition method or a liquid-phase deposition method. The second oxide semiconductor layer 550 may be formed by using the first oxide semiconductor pattern 540A as a seed crystal, which is similar to an epitaxial growth method.

The second oxide semiconductor layer 550 may decrease and/or prevent any impurities such as hydrogen from penetrating into the etched surface ES5 of the first oxide semiconductor pattern 540A. Furthermore, when the second oxide semiconductor layer 550 functions as a reservoir for impurities and contains a specific element, the effect of blocking the penetration of the impurity may be increased further. For example, the second oxide semiconductor layer 550 may include a gallium-rich oxide semiconductor with excellent hydrogen storage ability. Also, when another conductor, such as a contact plug, electrically connected to the second oxide semiconductor layer 550 is disposed over the second oxide semiconductor layer 550, an element that lowers the resistance when the second oxide semiconductor layer 550 is formed, for example, indium, may be further included in the second oxide semiconductor layer 550. As process similar to the process for forming the third oxide semiconductor layer 170 in accordance with the above-described embodiment of the present invention may be performed. In this case, the contact resistance between the first oxide semiconductor pattern 540A and another conductor may be decreased.

The first oxide semiconductor pattern 540A and the second oxide semiconductor layer 550 may correspond to the oxide semiconductor pattern 320 of FIG. 4 described above.

The embodiments of the present invention described above may be applied to all semiconductor devices and fabrication methods thereof that include NMOS transistors, PMOS transistors, or CMOS transistors. For example, they may be applied to non-volatile memories, such as a flash memory, a Resistive Random Access Memory (RRAM), a Phase-Change Random Access Memory (PRAM), a Magneto-resistive Random Access Memory (MRAM) and the like, volatile memories, such as a Dynamic Random Access Memory (DRAM), a Static Random Access Memory (SRAM) and the like, non-memory devices, such as a logic circuit and the like, and other diverse semiconductor devices, such as a CMOS Image Sensor (CIS) and the like.

According to the embodiments of the present invention, the semiconductor device and the method for fabricating the semiconductor device may be able to compensate for etching damage of an oxide semiconductor.

While the present invention has been described with respect to specific embodiments, it will be apparent to those skilled in the art that diverse changes and modifications may be made without departing from the technical concepts and scope of the invention as defined in the following claims. Furthermore, the embodiments may be combined to form additional embodiments.

What is claimed is:

1. A semiconductor device comprising:
a crystalline first oxide semiconductor pattern having at least one etched surface; and
a crystalline second oxide semiconductor layer disposed on the etched surface of the first oxide semiconductor pattern.

2. The semiconductor device of claim 1, wherein a roughness of the etched surface of the first oxide semiconductor pattern is greater than a roughness of a first surface of the second oxide semiconductor layer opposite to the etched surface.

3. The semiconductor device of claim 1, wherein a thickness or width of the second oxide semiconductor layer is smaller than a thickness or width of a portion of the first oxide semiconductor pattern corresponding to the etched surface.

4. The semiconductor device of claim 1, wherein the second oxide semiconductor layer includes a first element, and the first oxide semiconductor pattern does not contain the first element or contains the first element in a concentration lower than a concentration of the first element of the second oxide semiconductor layer.

5. The semiconductor device of claim 4, wherein
the first element contains gallium.

6. The semiconductor device of claim 1, wherein the second oxide semiconductor layer has a lower resistance than the first oxide semiconductor pattern.

7. The semiconductor device of claim 6, wherein the second oxide semiconductor layer includes indium, and
the first oxide semiconductor pattern does not contain indium or contains indium in a lower concentration than a concentration of indium of the second oxide semiconductor layer.

8. The semiconductor device of claim 6, further comprising:
a conductor,
wherein the second oxide semiconductor layer is interposed between the first oxide semiconductor pattern and the conductor.

9. The semiconductor device of claim 1, further comprising:
a gate structure disposed over the first oxide semiconductor pattern with a gate dielectric layer interposed therebetween; and
a contact plug disposed on at least one side surface of the gate structure over the first oxide semiconductor pattern,
wherein the second oxide semiconductor layer is interposed between the contact plug and the first oxide semiconductor pattern.

10. The semiconductor device of claim 9, wherein a side surface of the contact plug and a side surface of the second oxide semiconductor layer are aligned with each other.

11. The semiconductor device of claim 1, further comprising:
a gate structure disposed over the first oxide semiconductor pattern with a gate dielectric layer interposed therebetween,
wherein the second oxide semiconductor layer is interposed between the gate structure and the first oxide semiconductor pattern.

12. The semiconductor device of claim 1, wherein the etched surface corresponds to a side surface of the first oxide semiconductor pattern.

13. The semiconductor device of claim 12, wherein the first oxide semiconductor pattern has a pillar shape, and
the second oxide semiconductor pattern is formed to surround the side surface of the first oxide semiconductor pattern.

14. The semiconductor device of claim 1, wherein the etched surface corresponds to at least a portion of the top surface of the first oxide semiconductor pattern.

15. The semiconductor device of claim 14, wherein the first oxide semiconductor pattern has a pillar shape, and
the second oxide semiconductor pattern is formed to cover the top surface of the first oxide semiconductor pattern.

16. A method for fabricating a semiconductor device, the method comprising:
forming a crystalline first oxide semiconductor layer over a substrate;
forming a first oxide semiconductor pattern having an etched side surface by selectively etching the first oxide semiconductor layer; and
forming a crystalline second oxide semiconductor layer on the side surface of the first oxide semiconductor pattern.

17. The method of claim 16, wherein in forming the second oxide semiconductor layer,
a vapor deposition method or a liquid-phase deposition method is used.

18. The method of claim 16, further comprising:
after forming the first oxide semiconductor pattern,
forming an etched surface by exposing at least a portion of a top surface of the first oxide semiconductor pattern to an etching process; and
forming a third oxide semiconductor layer on the etched surface.

19. A method for fabricating a semiconductor device, the method comprising:
providing a crystalline first oxide semiconductor pattern over a substrate;
forming an etched surface by exposing at least a portion of a top surface of the first oxide semiconductor pattern to an etching process; and
forming a second oxide semiconductor layer on the etched surface.
